(19) United States
(12) Patent Application Publication
(10) Pub. No.: US 2022/0302125 A1
(43) Pub. Date: Sep. 22, 2022

(54) SEMICONDUCTOR MEMORY AND FORMING METHOD THEREOF

(71) Applicant: CHANGXIN MEMORY TECHNOLOGIES, INC., Hefei City (CN)

(72) Inventors: Yexiao YU, Hefei City (CN); Zhongming LIU, Hefei City (CN); Jia FANG, Hefei City (CN); Longyang CHEN, Hefei City (CN); Hongfa WU, Hefei City (CN)

(73) Assignee: CHANGXIN MEMORY TECHNOLOGIES, INC., Hefei City (CN)

(21) Appl. No.: 17/452,541

(22) Filed: Oct. 27, 2021

Related U.S. Application Data
(63) Continuation of application No. PCT/CN2021/114014, filed on Aug. 23, 2021.

(30) Foreign Application Priority Data
Mar. 19, 2021 (CN) 202110294504.9

(51) Int. Cl. H01L 27/108

(52) U.S. Cl. CPC H01L 27/10885; H01L 27/10814; H01L 27/10897; H01L 27/10855; H01L 27/10894

(57) ABSTRACT

A method of forming a semiconductor memory includes: providing comprising a storage area and a peripheral area located outside the storage area, wherein the substrate has and a plurality of bit line contact parts and a plurality of capacitor contact parts located in the storage area, and a peripheral gate contact part and a peripheral circuit contact part located in the peripheral area; forming a plurality of bit lines, and simultaneously forming a peripheral gate; forming a bit line isolation layer, and simultaneously forming a peripheral gate isolation layer; forming a first conductive capacitor layer in contact with the capacitor contact part, and simultaneously forming a first peripheral conductive layer in contact with the peripheral circuit contact part; forming a first air gap in the bit line isolation layer, and simultaneously forming a second air gap in the peripheral gate isolation layer.

### CROSS-REFERENCE TO RELATED APPLICATIONS

This is a continuation of International Patent Application No. PCT/CN2021/114014 filed on Aug. 23, 2021, which claims priority to Chinese Patent Application No. 202110294504.9 filed on Mar. 19, 2021. The disclosures of the above-referenced applications are incorporated by reference herein in their entirety.

### BACKGROUND

A Dynamic Random-Access Memory (DRAM) is a commonly used semiconductor structure in electronic devices, such as computers, and is composed of a plurality of storage units. Each of the storage units may include a transistor and a capacitor. A gate of the transistor is electrically connected with a word line, a source is electrically connected with a bit line, and a drain is electrically connected with the capacitor. Word line voltage on the word line may control the transistor to be turned on or turned off, to read data information stored in the capacitor through the bit line or write the data information into the capacitor.

### SUMMARY

The present disclosure relates to the technical field of semiconductor manufacturing, and in particular relates to a semiconductor memory and a forming method thereof.

According to the first aspect of the present application, the application provides a method of forming a semiconductor memory, which may include the following operations.

A substrate including a storage area and a peripheral area located outside the storage area is provided. The substrate has and a plurality of bit line contact parts and a plurality of capacitor contact parts located in the storage area, and a peripheral gate contact part and a peripheral circuit contact part located in the peripheral area.

A plurality of bit lines, each of which is in contact with a respective one of the bit line contact parts, are formed above the storage area, and simultaneously a peripheral gate in contact with the peripheral gate contact part is formed above the peripheral area.

A bit line isolation layer at least covering the side wall of the bit line is formed, and simultaneously a peripheral gate isolation layer at least covering the side wall of the peripheral gate is formed.

A first conductive capacitor layer in contact with the capacitor contact part is formed above the storage area, and simultaneously a first peripheral conductive layer in contact with the peripheral circuit contact part is formed above the peripheral area. The first conductive capacitor layer is filled in the gap between the adjacent bit lines, and the first peripheral conductive layer covers the side wall of the peripheral gate isolation layer.

A first air gap is formed in the bit line isolation layer, and simultaneously a second air gap is formed in the peripheral gate isolation layer.

According to the second aspect of the present application, the application provides a semiconductor memory, which may include a substrate, a plurality of bit lines, a peripheral gate, a bit line isolation layer, a peripheral gate isolation layer, a first air gap, a second air gap, a first conductive capacitor layer and a first peripheral conductive layer.

The substrate may include a storage area and a peripheral area located outside the storage area. The substrate has a plurality of bit line contact parts and a plurality of capacitor contact parts located in the storage area, and a peripheral gate contact part and a peripheral circuit contact part located in the peripheral area.

The plurality of bit lines are located above the storage area, each of the bit lines is in contact with a respective one of the bit line contact parts.

The peripheral gate is located above the peripheral area and in contact with the peripheral gate contact part.

The bit line isolation layer at least covers the side wall of the bit line.

The peripheral gate isolation layer at least covers the side wall of the peripheral gate.

The first air gap is located in the bit line isolation layer.

The second air gap is located in the peripheral gate isolation layer.

The first conductive capacitor layer is located above the storage area, in contact with the capacitor contact part, and is filled in the gap between the adjacent bit lines.

The first peripheral conductive layer is located above the peripheral area, in contact with the peripheral circuit contact part, and covers the side wall of the peripheral gate isolation layer.

### BRIEF DESCRIPTION OF THE DRAWINGS

FIG. 1 is a flowchart of a method of forming a semiconductor memory in a specific embodiment of the application.

FIG. 2A is a first schematic cross-sectional view of a storage area in a process of forming a semiconductor memory in an embodiment of the application.

FIG. 2B is a second schematic cross-sectional view of a storage area in a process of forming a semiconductor memory in an embodiment of the application.

FIG. 2C is a third schematic cross-sectional view of a storage area in a process of forming a semiconductor memory in an embodiment of the application.

FIG. 2D is a fourth schematic cross-sectional view of a storage area in a process of forming a semiconductor memory in an embodiment of the application.

FIG. 2E is a fifth schematic cross-sectional view of a storage area in a process of forming a semiconductor memory in an embodiment of the application.

FIG. 2F is a sixth schematic cross-sectional view of a storage area in a process of forming a semiconductor memory in an embodiment of the application.

FIG. 2G is a seventh schematic cross-sectional view of a storage area in a process of forming a semiconductor memory in an embodiment of the application.

FIG. 2H is an eighth schematic cross-sectional view of a storage area in a process of forming a semiconductor memory in an embodiment of the application.

FIG. 2I is a ninth schematic cross-sectional view of a storage area in a process of forming a semiconductor memory in an embodiment of the application.

FIG. 2J is a tenth schematic cross-sectional view of a storage area in a process of forming a semiconductor memory in an embodiment of the application.

FIG. 2K is an eleventh schematic cross-sectional view of a storage area in a process of forming a semiconductor memory in an embodiment of the application.

FIG. 2L twelfth a first schematic cross-sectional view of a storage area in a process of forming a semiconductor memory in an embodiment of the application.

FIG. 3A is a first schematic cross-sectional view of a peripheral area in a process of forming a semiconductor memory in an embodiment of the application.

FIG. 3B is a second schematic cross-sectional view of a peripheral area in a process of forming a semiconductor memory in an embodiment of the application.

FIG. 3C is a third schematic cross-sectional view of a peripheral area in a process of forming a semiconductor memory in an embodiment of the application.

FIG. 3D is a fourth schematic cross-sectional view of a peripheral area in a process of forming a semiconductor memory in an embodiment of the application.

FIG. 3E is a fifth schematic cross-sectional view of a peripheral area in a process of forming a semiconductor memory in an embodiment of the application.

FIG. 3F is a sixth schematic cross-sectional view of a peripheral area in a process of forming a semiconductor memory in an embodiment of the application.

FIG. 3G is a seventh schematic cross-sectional view of a peripheral area in a process of forming a semiconductor memory in an embodiment of the application.

FIG. 3H is an eighth schematic cross-sectional view of a peripheral area in a process of forming a semiconductor memory in an embodiment of the application.

FIG. 3I is a ninth schematic cross-sectional view of a peripheral area in a process of forming a semiconductor memory in an embodiment of the application.

### DETAILED DESCRIPTION

The embodiments of a semiconductor memory and a forming method thereof provided by the application are described in detail below in combination with the drawings.

The development of the DRAM pursues high speed, high integration density, low power consumption, etc. With the miniaturization of the structural size of a semiconductor device, especially in the manufacturing process of the DRAM with the key size less than 20 nm, there are higher requirements for the material, the morphology, the size, the electrical performance and the like of the bit line, such as wider bandwidth, to ensure good insulation performance and lower dielectric constant so as to ensure small parasitic capacitance and small coupling effect. Based on the above purpose, a variety of low dielectric constant materials are widely used in semiconductor manufacturing. In order to form a bit line with better performance, the bit line of a storage area and a peripheral structure device of a peripheral area are manufactured separately. The peripheral structure may include a peripheral gate, a peripheral circuit, etc. The separate manufacturing steps are quite cumbersome, the manufacturing cost is relatively high, and the performance of the bit line and a logic gate device after being manufactured needs to be improved.

Various embodiments of the present disclosure can address how to simplify the manufacturing steps of a semiconductor memory so as to reduce the manufacturing cost of the semiconductor memory and improve the performance of the semiconductor memory.

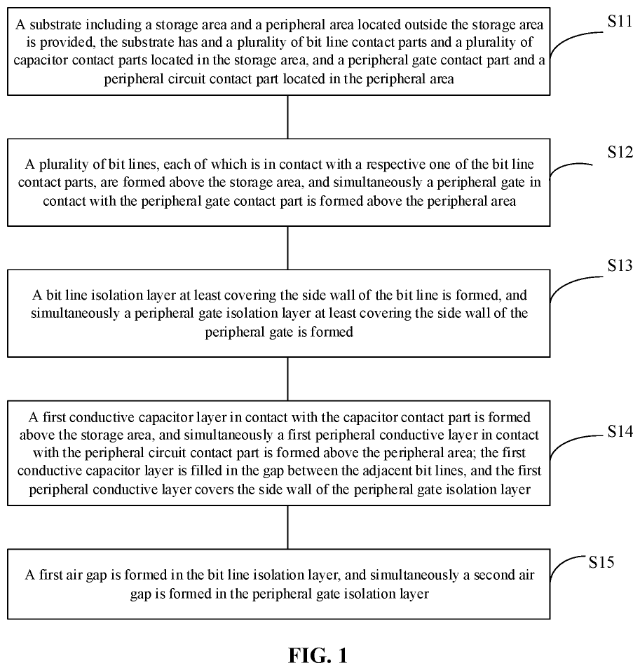

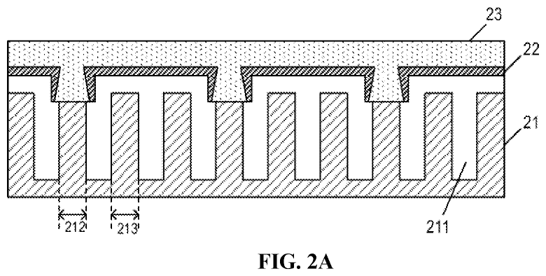

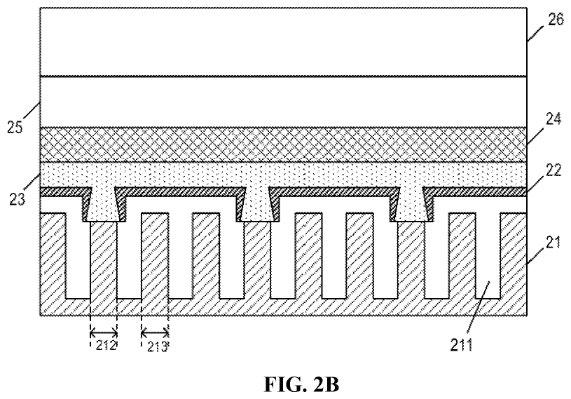

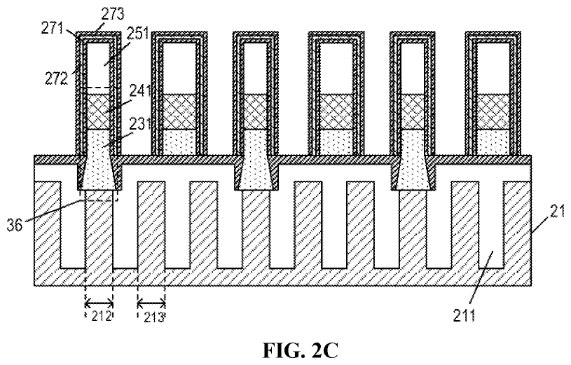

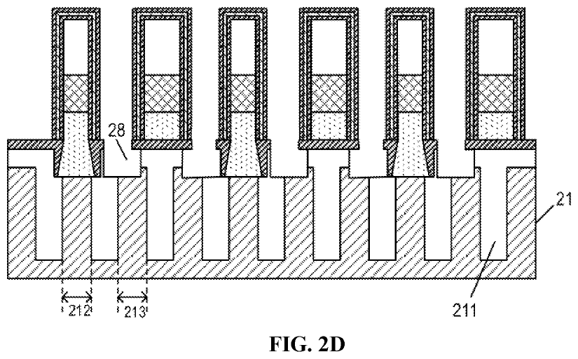

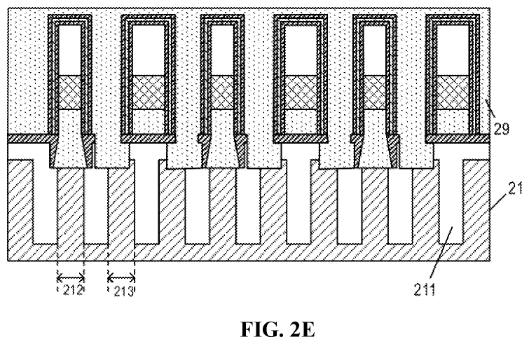

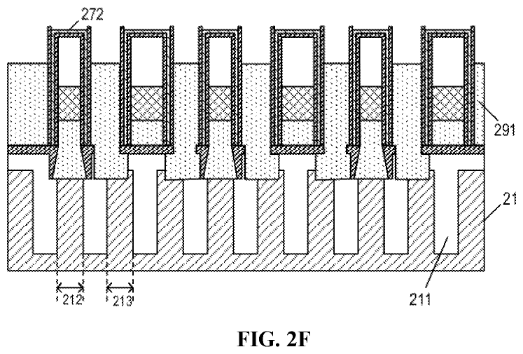

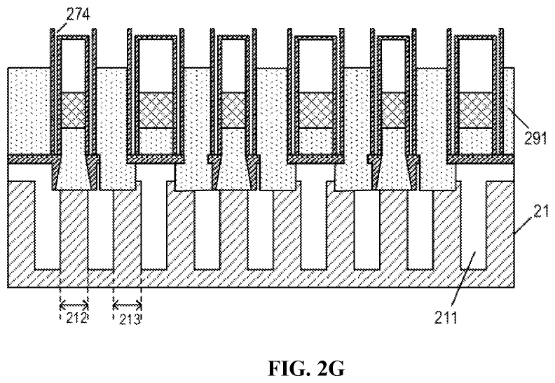

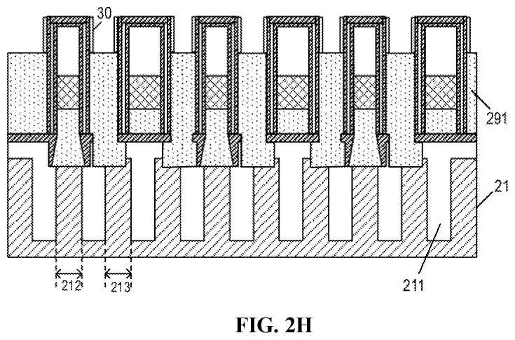

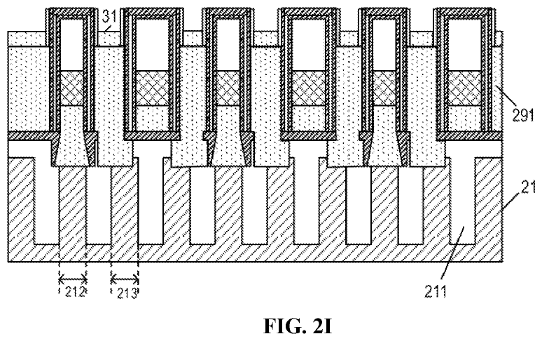

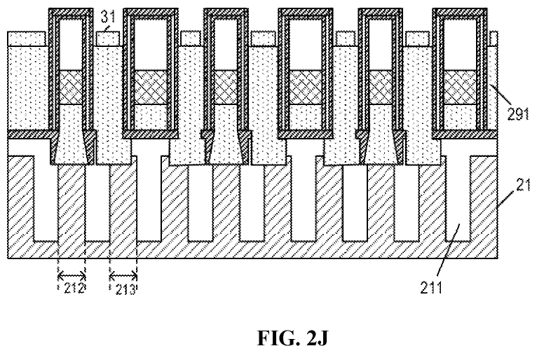

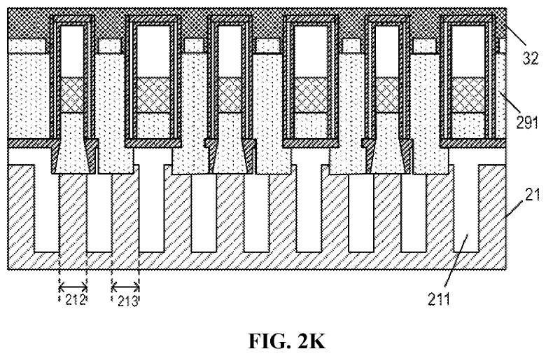

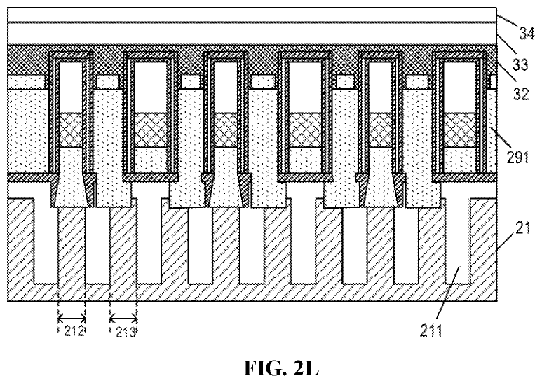

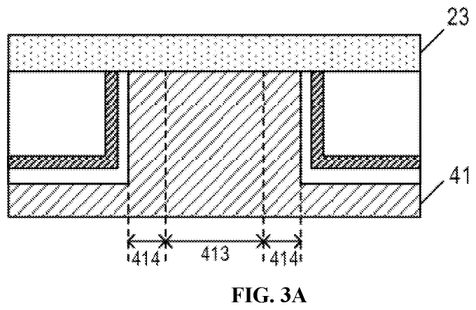

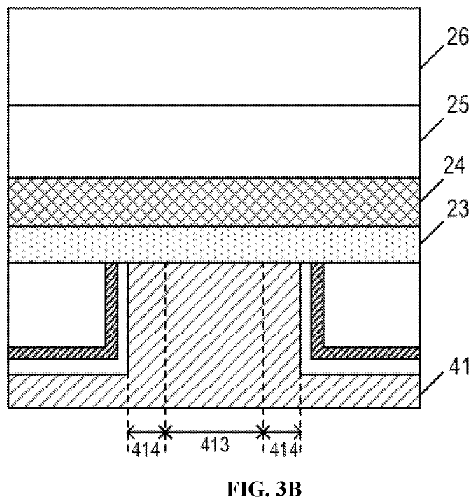

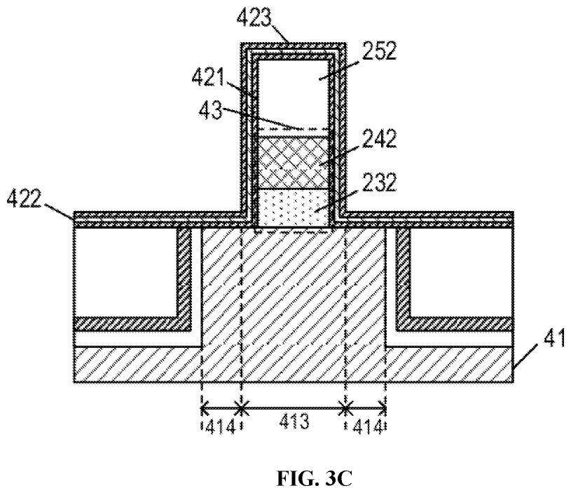

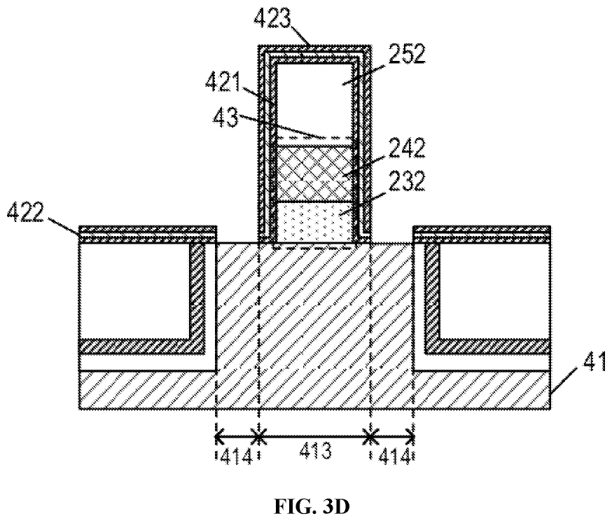

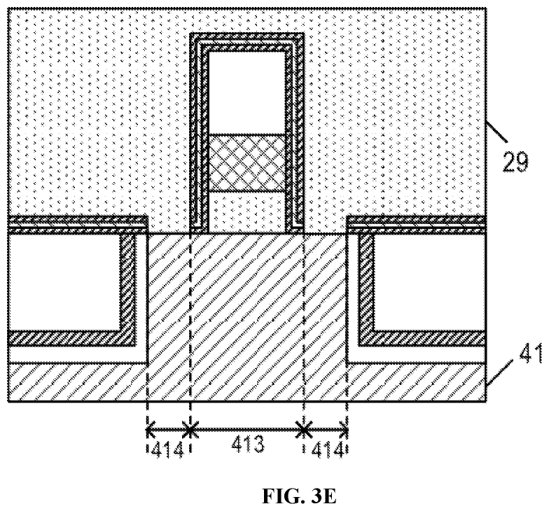

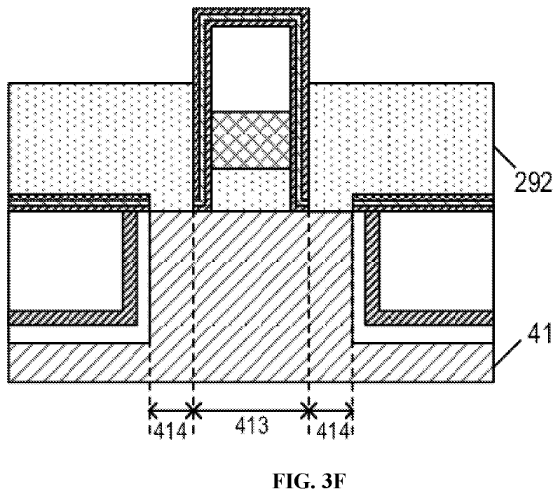

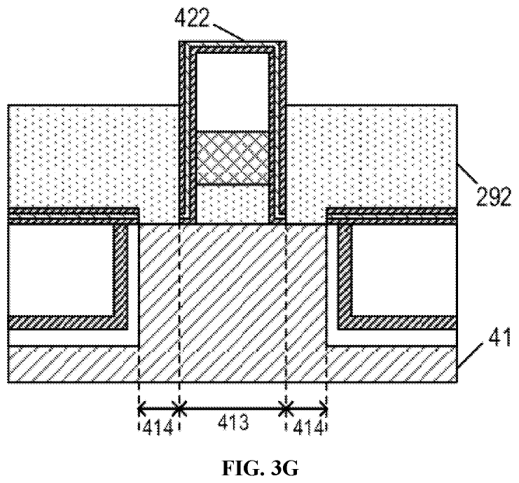

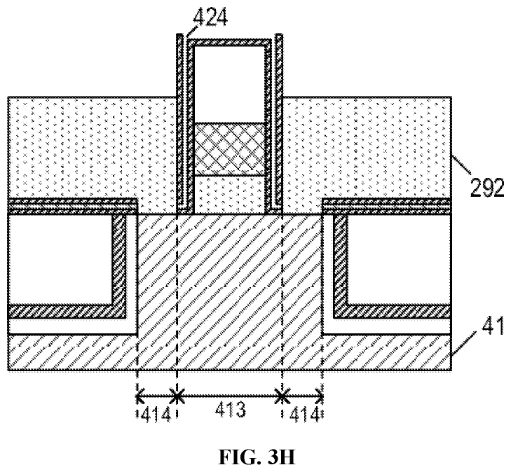

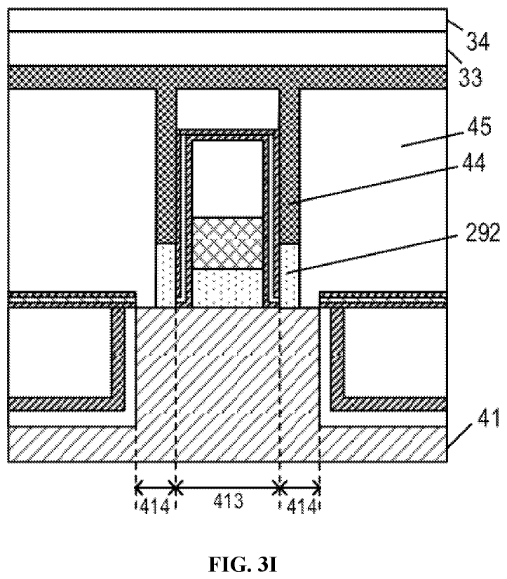

The embodiment provides a method of forming a semiconductor memory. FIG. 1 is a flowchart of a method of forming a semiconductor memory in an embodiment of the application. FIG. 2A to FIG. 2L are schematic cross-sectional views of a storage area in a process of forming a semiconductor memory in an embodiment of the application. FIG. 3A to FIG. 3I are schematic cross-sectional views of a peripheral area in a process of forming a semiconductor memory in an embodiment of the application. As shown in FIG. 1, FIG. 2A to FIG. 2L and FIG. 3A to FIG. 3I, a method of forming a semiconductor memory provided in the embodiment may include the follows.

At S11, a substrate is provided. The substrate may include a storage area 21 and a peripheral area 41 located outside the storage area 21. The substrate has a plurality of bit line contact parts 212 and a plurality of capacitor contact parts 213 located in the storage area 21, and a peripheral gate contact part 413 and a peripheral circuit contact part 414 located in the peripheral area 41, as shown in FIG. 2A and FIG. 3A.

Specifically, the substrate may be, but is not limited to, a silicon substrate. The substrate may include the storage area 21 and the peripheral area 41 located outside the storage area. The peripheral area 41 may be only located on one side of the storage area 21 or distributed around the storage area 21. The storage area 21 is configured to store data information, and the peripheral area 41 may include a Complementary Metal Oxide Semiconductor (CMOS) circuit and other structures for transmitting a control signal to the storage area 21. The storage area 21 in the substrate may include the plurality of bit line contact parts 212 and the plurality of capacitor contact parts 213. The bit line contact parts 212 and the capacitor contact parts 213 are alternately arranged in the substrate. The bit line contact part 212 is configured to be electrically connected with the subsequently formed bit line, and the capacitor contact part 213 is configured to be electrically connected with a subsequently formed capacitor contact structure. The peripheral area 41 in the substrate may include the peripheral gate contact part 413 and the peripheral circuit contact part 414. The peripheral gate contact part 413 is configured to be electrically connected with the subsequently formed peripheral gate, and the peripheral circuit contact part 414 is configured to be electrically connected with the subsequently formed peripheral circuit.

At S12, a plurality of bit lines 36, each of which is in contact with a respective one of the plurality of bit line contact parts 212, are formed above the storage area 21; and simultaneously a peripheral gate 43 in contact with the peripheral gate contact part 413 is formed above the peripheral area 41, as shown in FIG. 2C and FIG. 3C.

In some embodiments, the formation of a plurality of bit lines 26, each of which is in contact with a respective one of the plurality of bit line contact parts 212, above the storage area 21 and the formation of the peripheral gate 43 in contact with the peripheral gate contact part 413 above the peripheral area 41 may include the following operations.

A bit line material layer is formed on the surface of the substrate, and the bit line material layer at least covers the bit line contact parts 212 of the storage area 21 and the peripheral gate contact part 413 of the peripheral area 41, as shown in FIG. 2B and FIG. 3B.

The bit line material layer 22 is patterned, the bit lines 26 in contact with the bit line contact parts 212 are formed in the storage area 21, and simultaneously the peripheral gate 43 in contact with the peripheral gate contact part 413 is formed in the peripheral area 41, as shown in FIG. 2C and FIG. 3C.

In order to reduce the contact resistance between the bit line and the bit line contact part and between the peripheral gate and the peripheral gate contact part, and improve the electrical performance of the semiconductor memory, in some embodiments, the formation of the bit line material layer on the surface of the substrate may include the following operations.

A first conductive layer 23 is formed on the surface of the substrate, and the first conductive layer 23 at least covers the bit line contact parts 212 of the storage area 21 and the peripheral gate contact part 413 of the peripheral area 41, as shown in FIG. 2A and FIG. 3A.

A second conductive layer 24 covering the first conductive layer 23 is formed, as shown in FIG. 2B and FIG. 3B.

A first dielectric layer 25 covering the second conductive layer 24 is formed, as shown in FIG. 2B and FIG. 3B.

In some embodiments, the patterning of the bit line material layer may include the following operations.

The first dielectric layer 25, the second conductive layer 24 and the first conductive layer 23 are etched to form bit lines 26 in contact with the bit line contact parts 212, and form bit line cover layer 251 located on the top surface of each bit line 26 in the storage area 21; and simultaneously form a peripheral gate 43 in contact with the peripheral gate contact part 413 and a peripheral gate cover layer 252 covering the top surface of the peripheral gate 43 in the peripheral area 41.

Specifically, as shown in FIG. 2A and FIG. 3A, the first conductive layer 23 is deposited on the surface of the substrate, and the first conductive layer 23 covers the bit line contact parts 212 of the storage area 21 of the substrate and the peripheral gate contact part 413 of the peripheral area 41. The first conductive layer 23 may continuously cover the entire surface of the substrate, or may only cover the bit line contact parts 212 of the storage area 21 and the peripheral gate contact part 413 of the peripheral area 41. Then, the second conductive layer 24 is deposited on the surface of the first conductive layer 23. The material of the second conductive layer 24 may be different from that of the first conductive layer 23. For example, the material of the first conductive layer 23 is polysilicon, and the material of the second conductive layer 24 is a metal material (such as tungsten). Then, the first dielectric layer 25 is deposited on the surface of the second conductive layer 24 to form a structure as shown in FIG. 2B and FIG. 3B. The material of the first dielectric layer 25 may be, but is not limited to, a nitride material (such as silicon nitride). The first conductive layer 23, the second conductive layer 24 and the first dielectric layer 25 together form the bit line material layer. Those skilled in the art may also select other materials or a stack of other numbers of layers as the bit line material layer according to the actual requirements.

After the bit line material layer is formed in the storage area 21 and the peripheral area 41, a first mask layer 26 covering the bit line material layer is formed. After the first mask layer 26 is patterned, the bit line material layer is etched to simultaneously form the bit lines 36 and the peripheral gate 43, and to simultaneously form the bit line cover layer 251 located on the surface of each bit line 36 and the peripheral gate cover layer 252 located on the surface of the peripheral gate 43. Each bit line 36 may include a bit line contact layer 231 and a bit line body layer 241 covering the surface of the bit line contact layer 231. The bit line contact layer 231 is formed by the first conductive layer 23 remaining in the storage area 21 after the bit line material layer is etched, and the bit line body layer 241 is formed by the second conductive layer 24 remaining in the storage area 21 after the bit line material layer is etched. The peripheral gate 43 may include a peripheral gate contact layer 232 and a peripheral gate body layer 242 covering the surface of the peripheral gate contact layer 232. The peripheral gate contact layer 232 is formed by the first conductive layer 23 remaining in the peripheral area 41 after the bit line material layer is etched, and the peripheral gate body layer 242 is formed by the second conductive layer 24 remaining in the peripheral area 41 after the bit line material layer is etched.

At S13, a bit line isolation layer at least covering the side wall of the bit line 36 is formed, and simultaneously a peripheral gate isolation layer at least covering the side wall of the peripheral gate 43 is formed, as shown in FIG. 2C and FIG. 3C.

In some embodiments, the formation of the bit line isolation layer at least covering the side wall of the bit line 36 and the formation of the peripheral gate isolation layer at least covering the side wall of the peripheral gate 43 may include the following operations.

A first isolation layer at least covering the side wall of the bit line 36, the side wall of the bit line cover layer 251, the side wall of the peripheral gate 43 and the side wall of the peripheral gate cover layer 252 is formed.

A second isolation layer covering the first isolation layer is formed.

A third isolation layer covering the second isolation layer is formed. A part of the first isolation layer covering the side wall of the bit line 36 and the side wall of the bit line cover layer 251, the second isolation layer and the third isolation layer form the bit line isolation layer, and a part of the first isolation layer covering the side wall of the peripheral gate 43 and the side wall of the peripheral gate cover layer 252, the second isolation layer and the third isolation layer form the peripheral gate isolation layer.

Specifically, the first isolation layer, the second isolation layer and the third isolation layer are sequentially deposited on the side wall of the bit line 36, the side wall and top surface of the bit line cover layer 251, the side wall of the peripheral gate 43, and the side wall and top surface of the peripheral gate cover layer 252. Then, the first isolation layer, the second isolation layer and the third isolation layer are etched. The first isolation layer (i.e., a first sub bit line isolation layer 271), the second isolation layer (i.e., a second sub bit line isolation layer 272) and the third isolation layer (i.e., a third sub bit line isolation layer 273) remaining at the side wall of the bit line 36 and the side wall of the bit line cover layer 251 serve as the bit line isolation layer. The part of the first isolation layer (i.e., a first sub peripheral gate isolation layer 421), the second isolation layer (i.e., a second sub peripheral gate isolation layer 422) and the third isolation layer (i.e., a third sub peripheral gate isolation layer 423) covering the side wall of the peripheral gate 43 and the side wall of the peripheral gate cover layer 252 serve as the peripheral gate isolation layer. The materials of the first isolation layer and the third isolation layer may be the same, for example, both are nitride materials (such as silicon nitride), and the material of the second isolation layer may be an oxide material (such as silicon oxide). The second isolation layer shall have a relatively high etching selection ratio with respect to the first isolation layer and the third isolation layer, so as to facilitate the subsequent removal of the second isolation layer and form an air gap.

At S14, a first conductive capacitor layer 291 in contact with the capacitor contact part 213 is formed above the storage area 21, and simultaneously a first peripheral conductive layer 292 in contact with the peripheral circuit contact part 414 is formed above the peripheral area 41. The first conductive capacitor layer 291 fills the gap between the adjacent bit lines 36, and the first peripheral conductive layer 292 covers the side wall of the peripheral gate isolation layer, as shown in FIG. 2F and FIG. 3F.

In some embodiments, the formation of the first conductive capacitor layer 291 in contact with the capacitor contact part 213 above the storage area 21 and formation of the first peripheral conductive layer 292 in contact with the peripheral circuit contact part 414 above the peripheral area 41 may include the following operations.

The storage area 21 and the peripheral area 41 of the substrate are etched, to expose the capacitor contact part 213 and the peripheral circuit contact part 414 simultaneously, as shown in FIG. 2D and FIG. 3D.

A third conductive layer 29 filling the gap between the adjacent bit lines 36 and covering the capacitor contact part 213, the peripheral circuit contact part 414, the bit line isolation layer and the peripheral gate isolation layer is formed, as shown in FIG. 2E and FIG. 3E.

Part of the third conductive layer 29 is removed to allow the top surface of the third conductive layer 29 to be located below the bit line cover layer 251 and the peripheral gate cover layer 252. A part of the third conductive layer 29 remaining in the storage area 21 forms the first conductive capacitor layer 291, and a part of the third conductive layer 29 remaining in the peripheral area 41 forms the first peripheral conductive layer 292.

Specifically, the storage area 21 and the peripheral area 41 of the substrate are etched, and the capacitor contact part 213 and the peripheral circuit contact part 414 are simultaneously exposed. A groove 28 is formed in the substrate while the storage area 21 is etched. Then, the third conductive layer 29 is deposited to fill the groove 28 and the gap between the adjacent bit lines 36, and cover the capacitor contact part 213, the peripheral circuit contact part 414, the surface of the bit line isolation layer and the surface of the peripheral gate isolation layer. Then, part of the third conductive layer 29 is etched to form the first conductive capacitor layer 291 in the storage area 21 and simultaneously form the peripheral conductive layer 292 in the peripheral area 41. The material of the third conductive layer 29 may be, but is not limited to, polysilicon.

At S15, a first air gap 274 is formed in the bit line isolation layer, and simultaneously a second air gap 424 is formed in the peripheral gate isolation layer, as shown in FIG. 2G and FIG. 3H.

In some embodiments, the formation of the first air gap 274 in the bit line isolation layer and the second air gap 424 in the peripheral gate isolation layer may include the following operations.

The second isolation layer is removed, the first air gap 274 is formed at the side wall of the bit line 36 and the side wall of the bit line cover layer 251 and located between the first isolation layer and the third isolation layer, and simultaneously the second air gap 424 is formed at the side wall of the peripheral gate 43 and the side wall of the peripheral gate cover layer 252 and located between the first isolation layer and the third isolation layer.

In some embodiments, the third isolation layer also covers the top surface of the bit line cover layer 251 and the top surface of the peripheral gate cover layer 252. The removal of the second isolation layer may include the following operations.

A part of the third isolation layer covering the top surfaces of the bit line cover layer 251 and the peripheral gate cover layer 252 is removed, and the second isolation layer is exposed.

All of the second isolation layers are etched away.

Specifically, after the first conductive capacitor layer 291 and the first peripheral conductive layer 292 are formed, the third sub bit line isolation layer 273 and the third sub peripheral gate isolation layer 423 are synchronously etched to expose the second sub bit line isolation layer 272 and the second sub peripheral gate isolation layer 422, as shown in FIG. 2F and FIG. 3G. Then, the second sub bit line isolation layer 272 in the bit line isolation layer and the second sub peripheral gate isolation layer 422 in the peripheral gate isolation layer are removed by a wet etching process, and the first air gap 274 and the second air gap 424 are formed simultaneously.

In the specific embodiment, by forming the first air gap 274 and the second air gap 424, the parasitic capacitance of the bit line 36 and the peripheral gate 43 may be greatly reduced, and the contact resistance between the first conductive capacitor layer 291 and the capacitor contact part 213 may be reduced. Moreover, since the first air gap 274 and the second air gap 424 are directly formed by an etching process after the third conductive layer 29 is directly filled and the first conductive capacitor layer 291 and the first peripheral conductive layer 292 are formed, the operations of forming the air gap can be simplified and the efficiency of the semiconductor process can be improved.

In some embodiments, the top surface of the first conductive capacitor layer 291 is located below the top surface of the bit line cover layer 251. After the first air gap 274 is formed in the bit line isolation layer and the second air gap 424 is formed in the peripheral gate isolation layer, it may also include the following operations.

An auxiliary layer 30 covering the side wall of the bit line isolation layer is formed, as shown in FIG. 2H.

A fourth conductive layer 31 covering the top surface of the first conductive capacitor layer 291 and the side wall of the auxiliary layer 30 is formed, as shown in FIG. 2I.

The auxiliary layer 30 is removed to form a capacitor contact structure including the fourth conductive layer 31 and the first conductive capacitor layer 291, as shown in FIG. 2J.

Specifically, by depositing the fourth conductive layer 31 after the auxiliary layer 30 is formed at the side wall of the bit line isolation layer, the stepped capacitor contact structure can be obtained after the auxiliary layer 30 is removed. In the stepped capacitor contact structure, the width of the fourth conductive layer 31 in the direction parallel to the substrate is less than that of the top surface of the first conductive capacitor layer 291 (i.e., the surface of the first conductive capacitor layer 291 which contacts the fourth conductive layer 31). The stepped capacitor contact structure helps to increase the contact area between the subsequently formed second conductive capacitor layer and the capacitor contact structure, so as to reduce the capacitor contact resistance. In the specific embodiment, a capacitor hole is the gap between the adjacent bit lines 36.

In some embodiments, after the capacitor contact structure including the fourth conductive layer 31 and the first conductive capacitor layer 291 is formed, the method may also include the following operations.

A second conductive capacitor layer 32 covering the surface of the capacitor contact structure is formed, and simultaneously a second peripheral conductive layer 44 covering the surface of the first peripheral conductive layer 292 is formed, as shown in FIG. 2K and FIG. 3I.

Specifically, after the first peripheral conductive layer 292 as shown in FIG. 3H is formed, a part of the first peripheral conductive layer 292 outside the peripheral circuit contact part 414 and above part of the peripheral circuit contact part 414 is partially removed to form the first peripheral conductive layer 292 as shown in FIG. 3I. Then, a second dielectric layer 45 is deposited on the surface of the substrate of the peripheral area 41, and the second dielectric layer 45 covers the peripheral circuit contact part 414 and the first peripheral conductive layer 292. Then, the second dielectric layer 45 is etched, to form a through hole, through which the top surface of the first peripheral conductive layer 292 (i.e., the surface of the first peripheral conductive layer 292 away from the peripheral circuit contact part 414) is exposed, in the second dielectric layer 45. The material of the second dielectric layer 45 may be an oxide material, such as silicon oxide. Then, a second conductive capacitor layer 32 covering the surface of the capacitor contact structure is formed, and simultaneously a second peripheral conductive layer 44 filling the through hole and covering the surface of the second dielectric layer 45 is formed, as shown in FIG. 2K and FIG. 3I.

After the second conductive capacitor layer 32 and the second peripheral conductive layer 44 are formed, a third dielectric layer 33 covering both the second conductive capacitor layer 32 and the second peripheral conductive layer 44, and a fourth dielectric layer 34 located on the surface of the third dielectric layer 33 may also be formed. The material of the third dielectric layer 33 may be Amorphous Carbon (ACL), and the material of the fourth dielectric layer 34 may be a nitrogen oxide material, such as silicon oxynitride.

Moreover, the application further provides a semiconductor memory. The semiconductor memory provided in the specific embodiment may be formed by the method shown in FIG. 1, FIG. 2A to FIG. 2L and FIG. 3A to FIG. 3I. The specific structure of the semiconductor memory provided in the specific embodiment may refer to FIG. 2L and FIG. 3I. As shown in FIG. 2A to FIG. 2L and FIG. 3A to FIG. 3I, the semiconductor memory provided in the specific embodiment may include a substrate, a plurality of bit lines 36, a peripheral gate 43, a bit line isolation layer, a peripheral gate isolation layer, a first air gap 274, a second air gap 424, a first conductive capacitor layer 291 and a first peripheral conductive layer 292.

The substrate may include a storage area 21 and a peripheral area 41 located outside the storage area 21. The substrate has a plurality of bit line contact parts 212 and a plurality of capacitor contact parts 213 located in the storage area 21, and a peripheral gate contact part 413 and a peripheral circuit contact part 414 located in the peripheral area 41.

The plurality of bit lines 36 are located above the storage area 21, and each of the bit lines 36 is in contact with a respective one of the bit line contact parts 212.

The peripheral gate 43 is located above the peripheral area 41 and in contact with the peripheral gate contact part 413.

The bit line isolation layer at least covers the side wall of the bit line 36.

The peripheral gate isolation layer at least covers the side wall of the peripheral gate 43.

The first air gap 274 is located in the bit line isolation layer.

The second air gap 424 is located in the peripheral gate isolation layer.

The first conductive capacitor layer 291 is located above the storage area 21, in contact with the capacitor contact part 213, and filled in the gap between the adjacent bit lines 36.

The first peripheral conductive layer 292 is located above the peripheral area 41, in contact with the peripheral circuit contact part 414, and covers the side wall of the peripheral gate isolation layer.

In some embodiments, the semiconductor memory may also include a bit line cover layer 251 and a peripheral gate cover layer 252.

The bit line cover layer 251 is located on the top surface of the bit line 36, and the bit line isolation layer also covers the side wall of the bit line cover layer 251.

The peripheral gate cover layer 252 is located on the top surface of the peripheral gate 43, and the peripheral gate isolation layer also covers the side wall of the peripheral gate cover layer 252.

In some embodiments, the semiconductor memory may also include a fourth conductive layer 31.

The fourth conductive layer 31 is located on the top surface of the first conductive capacitor layer 291. The width of the fourth conductive layer 31 in the direction parallel to the surface of the substrate is less than that of the first conductive capacitor layer 291.

In some embodiments, the semiconductor memory may also include a second conductive capacitor layer 32 and a second peripheral conductive layer 44.

The second conductive capacitor layer 32 covers the surface of the fourth conductive layer 31 and the surface of the first conductive capacitor layer 291.

The second peripheral conductive layer 44 covers the surface of the first peripheral conductive layer 292.

In some embodiments, the bit line isolation layer may include a first sub bit line isolation layer 271 and a third sub bit line isolation layer 273. The first air gap 274 is located between the first sub bit line isolation layer 271 and the third sub bit line isolation layer.

The peripheral gate isolation layer may include a first sub peripheral gate isolation layer 421 and a third sub peripheral gate isolation layer 423, and the second air gap 424 is located between the first sub peripheral gate isolation layer 421 and the third sub peripheral gate isolation layer 423.

According to the semiconductor memory and the forming method thereof provided in the specific embodiment, by forming the bit line in the storage area and the peripheral gate in the peripheral area, and by forming the bit line isolation layer covering the side wall of the bit line and having the first air gap and the peripheral gate isolation layer covering the side wall of the peripheral gate and having the second air gap at the same time, the manufacturing steps of the semiconductor memory are simplified, and the manufacturing cost of the semiconductor memory is reduced. Moreover, the formation of the first air gap and the second air gap greatly reduces the parasitic capacitance of the bit line and the peripheral gate, and improves the electrical performance of the semiconductor memory.

The above is only the preferred embodiment of the application. It should be noted that ordinary technicians in the technical field may also make several improvements and refinements without departing from the principles of the application, and these improvements and refinements should also be regarded as the scope of protection of the application.

What is claimed is:

1. A method of forming a semiconductor memory, comprising:
providing a substrate comprising a storage area and a peripheral area located outside the storage area, wherein the substrate has and a plurality of bit line contact parts and a plurality of capacitor contact parts located in the storage area, and a peripheral gate contact part and a peripheral circuit contact part located in the peripheral area;
forming a plurality of bit lines, each of which is in contact with a respective one of the bit line contact parts, above the storage area, and simultaneously forming a peripheral gate in contact with the peripheral gate contact part above the peripheral area;
forming a bit line isolation layer at least covering a side wall of the bit line, and simultaneously forming a peripheral gate isolation layer at least covering a side wall of the peripheral gate;
forming a first conductive capacitor layer in contact with the capacitor contact part above the storage area, and simultaneously forming a first peripheral conductive layer in contact with the peripheral circuit contact part above the peripheral area, wherein the first conductive capacitor layer is filled in the gap between the adjacent bit lines, and the first peripheral conductive layer covers the side wall of the peripheral gate isolation layer; and
forming a first air gap in the bit line isolation layer, and simultaneously forming a second air gap in the peripheral gate isolation layer.

2. The method of forming the semiconductor memory according to claim 1, wherein forming a plurality of bit lines, each of which is in contact with a respective one of the bit line contact parts, above the storage area, and simultaneously forming a peripheral gate in contact with the peripheral gate contact part above the peripheral area comprises:
forming, a bit line material layer covering the bit line contact parts of the storage area and the peripheral gate contact part of the peripheral area, on a surface of the substrate, the bit line material layer at least; and
patterning the bit line material layer to form a bit line in contact with the bit line contact part in the storage area and simultaneously form a peripheral gate in contact with the peripheral gate contact part in the peripheral area.

3. The method of forming the semiconductor memory according to claim 2, wherein forming the bit line material layer on the surface of the substrate comprises:
forming, a first conductive layer at least covering the bit line contact part of the storage area and the peripheral gate contact part of the peripheral area, on the surface of the substrate;
forming a second conductive layer covering the first conductive layer; and
forming a first dielectric layer covering the second conductive layer.

4. The method of forming the semiconductor memory according to claim 3, wherein patterning the bit line material layer comprises:
etching the first dielectric layer, the second conductive layer and the first conductive layer, to form the bit lines in contact with the bit line contact parts and a bit line cover layer located on top surfaces of the bit lines in the storage area and simultaneously form a peripheral gate in contact with the peripheral gate contact part and a peripheral gate cover layer covering a top surface of the peripheral gate in the peripheral area.

5. The method of forming the semiconductor memory according to claim 4, wherein forming the bit line isolation layer at least covering the side wall of the bit line and simultaneously forming the peripheral gate isolation layer at least covering the side wall of the peripheral gate comprises:
forming a first isolation layer at least covering the side wall of the bit line, a side wall of the bit line cover layer, the side wall of the peripheral gate and a side wall of the peripheral gate cover layer;
forming a second isolation layer covering the first isolation layer; and
forming a third isolation layer covering the second isolation layer, wherein a part of the first isolation layer covering the side wall of the bit line and the side wall of the bit line cover layer, the second isolation layer and the third isolation layer form the bit line isolation layer, and a part of the first isolation layer covering the side wall of the peripheral gate and the side wall of the peripheral gate cover layer, the second isolation layer and the third isolation layer form the peripheral gate isolation layer.

6. The method of forming the semiconductor memory according to claim 5, wherein forming the first air gap in the bit line isolation layer and simultaneously forming the second air gap in the peripheral gate isolation layer comprises:
removing the second isolation layer, to form the first air gap at the side wall of the bit line and the side wall of the bit line cover layer and between the first isolation layer and the third isolation layer, and simultaneously form the second air gap at the side wall of the peripheral gate and the side wall of the peripheral gate cover layer and between the first isolation layer and the third isolation layer.

7. The method of forming the semiconductor memory according to claim 6, wherein the first isolation layer also covers a top surface of the bit line cover layer and a top surface of the peripheral gate cover layer; and removing the second isolation layer comprises:
removing the third isolation layer covering the top surfaces of the bit line cover layer and the peripheral gate cover layer, to expose the second isolation layer; and
etching away all of the second isolation layer.

8. The method of forming the semiconductor memory according to claim 1, wherein forming the first conductive capacitor layer in contact with the capacitor contact part above the storage area and simultaneously forming the first peripheral conductive layer in contact with the peripheral circuit contact part above the peripheral area comprises:
etching the storage area and the peripheral area of the substrate, to expose the capacitor contact part and the peripheral circuit contact part simultaneously;
forming a third conductive layer filling the gap between the adjacent bit lines and covering the capacitor contact part, the peripheral circuit contact part, the bit line isolation layer and the peripheral gate isolation layer; and
removing part of the third conductive layer to allow a top surface of the third conductive layer to be located below the bit line cover layer and the peripheral gate cover layer, wherein a part of the third conductive layer remaining in the storage area forms the first conductive capacitor layer, and a part of the third conductive layer remaining in the peripheral area forms the first peripheral conductive layer.

9. The method of forming the semiconductor memory according to claim 8, wherein a top surface of the first conductive capacitor layer is located below a top surface of the bit line cover layer; after forming the first air gap in the bit line isolation layer and simultaneously forming the second air gap in the peripheral grid isolation layer, the method further comprises:
forming an auxiliary layer covering a side wall of the bit line isolation layer;
forming a fourth conductive layer covering the top surface of the first conductive capacitor layer and a side wall of the auxiliary layer; and
removing the auxiliary layer to form a capacitor contact structure comprising the fourth conductive layer and the first conductive capacitor layer.

10. The method of forming the semiconductor memory according to claim 9, after forming the capacitor contact structure comprising the fourth conductive layer and the first conductive capacitor layer, the method further comprises:
forming a second conductive capacitor layer covering a surface of the capacitor contact structure, and simultaneously forming a second peripheral conductive layer covering a surface of the first peripheral conductive layer.

11. The method of forming the semiconductor memory according to claim 3, wherein a material of the second conductive layer is different from that of the first conductive layer.

12. The method of forming the semiconductor memory according to claim 11, wherein the material of the first conductive layer is polysilicon, and the material of the second conductive layer is a metal material.

13. The method of forming the semiconductor memory according to claim 3, wherein a material of the first dielectric layer is a nitride material.

14. The method of forming the semiconductor memory according to claim 5, wherein a material of the first isolation layer is the same as that of the third isolation layer.

15. The method of forming the semiconductor memory according to claim 5, wherein a material of the second isolation layer is an oxide material.

16. A semiconductor memory, comprising:
a substrate comprising a storage area and a peripheral area located outside the storage area, the substrate has a plurality of bit line contact parts and a plurality of capacitor contact parts located in the storage area, and a peripheral gate contact part and a peripheral circuit contact part located in the peripheral area;
a plurality of bit lines located above the storage area, each of the bit lines is in contact with a respective one of the bit line contact parts;
a peripheral gate located above the peripheral area and in contact with the peripheral gate contact part;
a bit line isolation layer at least covering a side wall of the bit line;
a peripheral gate isolation layer at least covering a side wall of the peripheral gate;
a first air gap located in the bit line isolation layer;
a second air gap located in the peripheral gate isolation layer;
a first conductive capacitor layer, which is located above the storage area, in contact with the capacitor contact part, and is filled in the gap between the adjacent bit lines; and
a first peripheral conductive layer, located above the peripheral area, in contact with the peripheral circuit contact part, and covering a side wall of the peripheral gate isolation layer.

17. The semiconductor memory according to claim 16, further comprising:
a bit line cover layer located on a top surface of the bit line, the bit line isolation layer also covers a side wall of the bit line cover layer; and
a peripheral gate cover layer located on a top surface of the peripheral gate, the peripheral gate isolation layer also covers a side wall of the peripheral gate cover layer.

18. The semiconductor memory according to claim 16, further comprising:
a fourth conductive layer located on the top surface of the first conductive capacitor layer, wherein the width of the fourth conductive layer in the direction parallel to a surface of the substrate is less than that of the first conductive capacitor layer.

19. The semiconductor memory according to claim 16, further comprising:
a second conductive capacitor layer covering a surface of the fourth conductive layer and a surface of the first conductive capacitor layer; and
a second peripheral conductive layer covering a surface of the first peripheral conductive layer.

20. The semiconductor memory according to claim 16, wherein the bit line isolation layer comprises a first sub bit line isolation layer and a third sub bit line isolation layer, and the first air gap is located between the first sub bit line isolation layer and the third sub bit line isolation layer;
the peripheral gate isolation layer comprises a first sub peripheral gate isolation layer and a third sub peripheral gate isolation layer, and the second air gap is located between the first sub peripheral gate isolation layer and the third sub peripheral gate isolation layer.
